(19) United States
(12) Patent Application Publication
(10) Pub. No.: US 2010/0164062 A1
(43) Pub. Date: Jul. 1, 2010

(54) METHOD OF MANUFACTURING THROUGH-SILICON-VIA AND THROUGH-SILICON-VIA STRUCTURE

(75) Inventors: Ching-Chiun Wang, Miaoli County (TW); Tai-Yuan Wu, Taipei City (TW); Yu-Sheng Chen, Taoyuan County (TW); Cha-Hsin Lin, Tainan City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/480,694

(22) Filed: Jun. 9, 2009

(30) Foreign Application Priority Data
Dec. 31, 2008 (TW) 97151896

(51) Int. Cl. H01L 29/92; H01L 21/02

(52) U.S. Cl. 257/532; 438/386; 438/667; 257/621; 257/E29.343; 257/E21.008

(57) ABSTRACT

A method of manufacturing through-silicon-via (TSV) and a TSV structure are provided. The TSV structure includes a silicon substrate, an annular capacitor, a conductive through-via, a layer of low-k material, and a bump. The annular capacitor is within the silicon substrate and constituted of a first conductive layer, a capacitor dielectric layer, and a second conductive layer from the inside to the outside. The conductive through-via is disposed in the silicon substrate surrounded by the annular capacitor, and the layer of low-k material is between the annular capacitor and the conductive through-via. The bump is in touch with the conductive through-via for bonding other chip.

### CROSS-REFERENCE TO RELATED APPLICATION

This application claims the priority benefit of Taiwan application serial no. 97151896, filed on Dec. 31, 2008. The entirety of the above-mentioned patent application is hereby incorporated by reference herein and made a part of this specification.

### BACKGROUND OF THE INVENTION

1. Field of the Invention

The present invention is related to a through-silicon-via (TSV) structure and a manufacturing method thereof.

2. Description of Related Art

Through-silicon-via (TSV) technology, which is to manufacture vertical through-vias passing through chips or wafers, is new three-dimensional integrated circuit technology that accomplishes interconnection between chips, as published on pages 491-506 of IBM J. RES. & DEV. Vol. 50 No. 4/5 by A. W. Topol et al. in 2006. Different from the conventional IC package technology and salient point stacking technology, TSV technology achieves the greatest density of stacking chips in three-dimensional directions, has the smallest size, improves the speed of the devices, reduces signal delay, and suppresses power consumption. Therefore, TSV is considered as a new generation of interconnect in 3D IC technology.

In recent years, study in annular TSV structure has been published. For instance, P. S. Andry et al. published “A CMOS-compatible Process for Fabricating Electrical Through-vias in Silicon” in the Electronic Components and Technology Conference in 2006. Compared with traditional cylindrical TSV, annular TSV structures have the advantages of reducing a cross section of a conductive layer, decreasing fabrication costs, and suppressing thermal stress. However, the annular TSV structures only provide the function of signal transmission.

### SUMMARY OF THE INVENTION

The present invention provides a method for manufacturing a through-silicon-via. In the method, a first annular trench is formed in a silicon substrate, and a first conductive layer, a capacitor dielectric layer, and a second conductive layer are then formed in the first annular trench, sequentially. Next, an opening is formed in the silicon substrate surrounded by the first annular trench. An insulating layer is then formed on an inner surface of the opening, and a conductive material is filled into the opening. Thereafter, a planarization process is performed on a back of the silicon substrate for removing a portion of the silicon substrate, which simultaneously removes the insulating layer from a bottom of the opening to form a conductive through-via and removes the first conductive layer and the capacitor dielectric layer from a bottom of the first annular trench. Then, the silicon substrate, the first conductive layer, and the capacitor dielectric layer between the insulating layer and the second conductive layer are removed to form a second annular trench. Further, a low-k material is filled into the second annular trench. Afterward, a bump contacting the conductive material on the bottom of the opening is formed.

The present invention further provides a through-silicon-via structure, including a silicon substrate, an annular capacitor, a conductive through-via, a layer of low-k material, and a bump. The annular capacitor is disposed in the silicon substrate and constituted of a first conductive layer, a capacitor dielectric layer, and a second conductive layer form the inside to the outside. The conductive through-via is positioned in the silicon substrate surrounded by the annular capacitor, and the layer of low-k material is located between the annular capacitor and the conductive through-via. The bump is in contact with the conductive through-via for bonding other chips.

To make the above features and advantages of the present invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1J are schematic cross-sectional views illustrating a process flow for manufacturing a through-silicon-via according to one embodiment of the present invention.

FIG. 2 illustrates a schematic top view of a through-silicon-via structure having a capacitance function according to another embodiment of the present invention.

FIG. 3 is a schematic cross-sectional view along Line III-III in FIG. 2.

### DESCRIPTION OF EMBODIMENTS

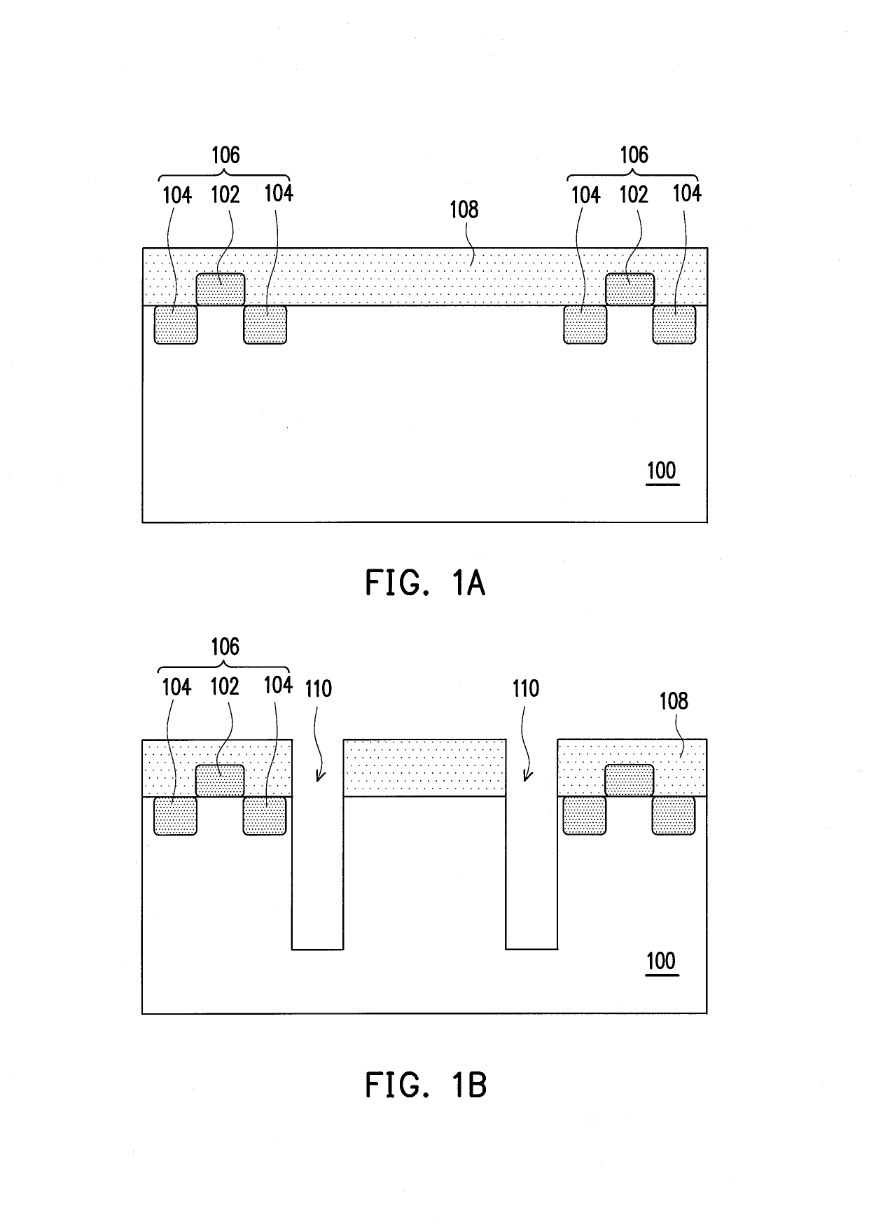

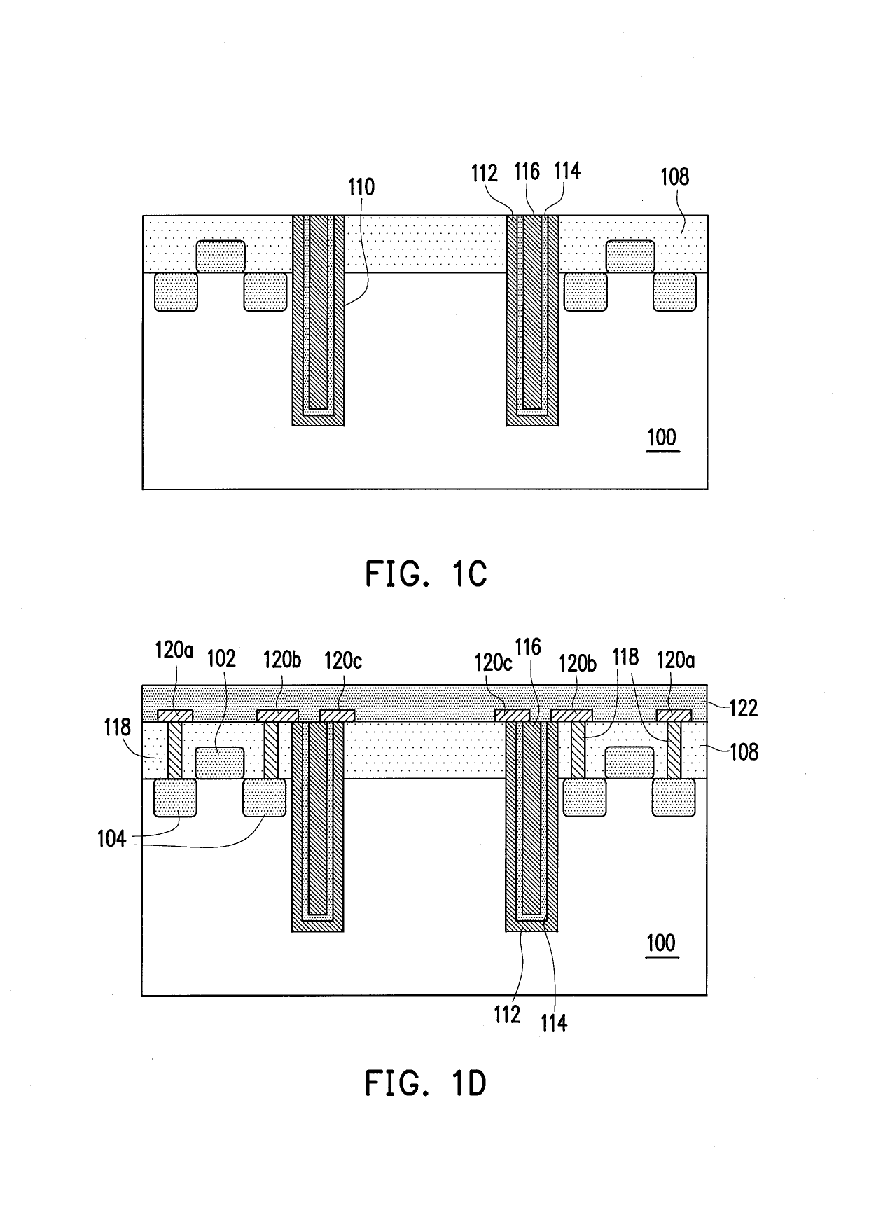

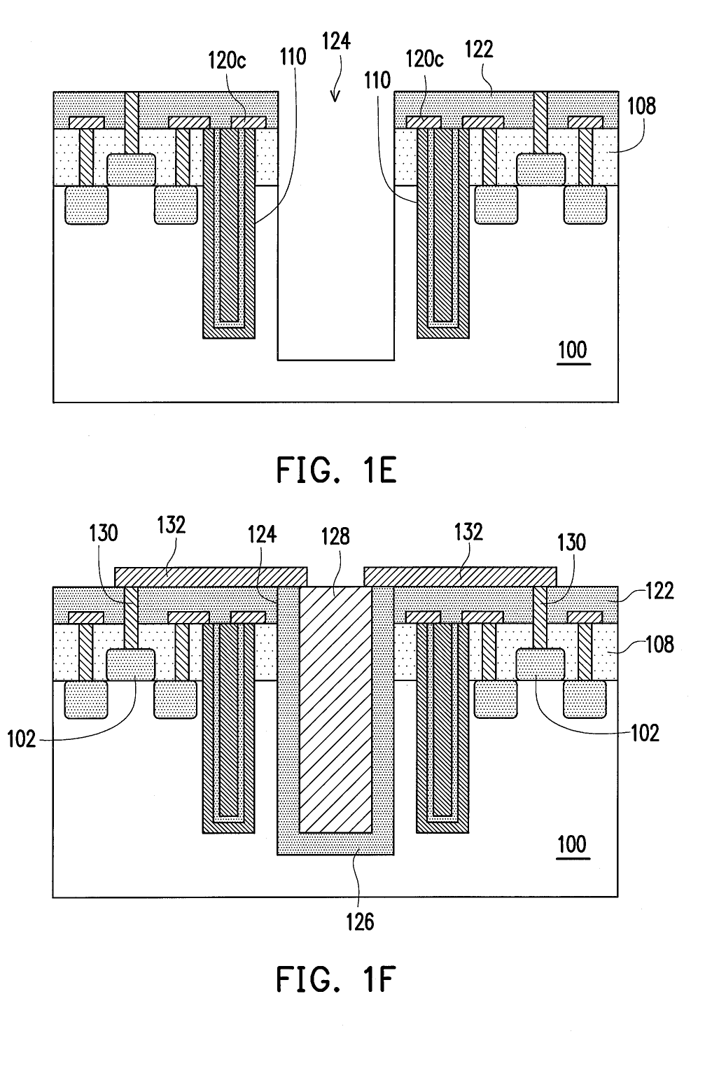

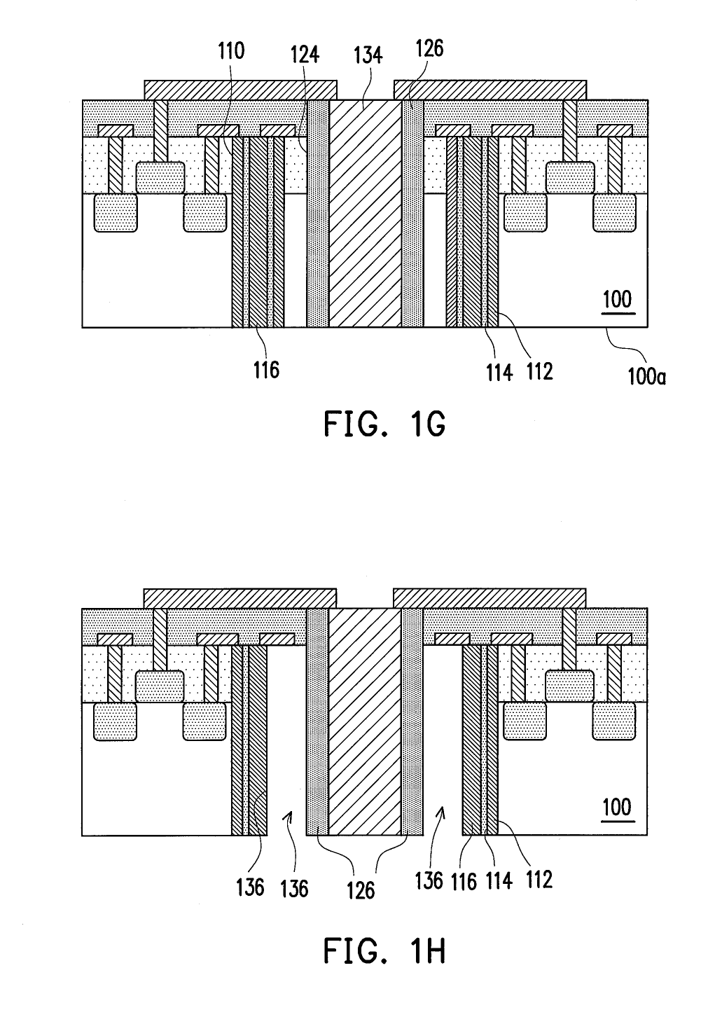

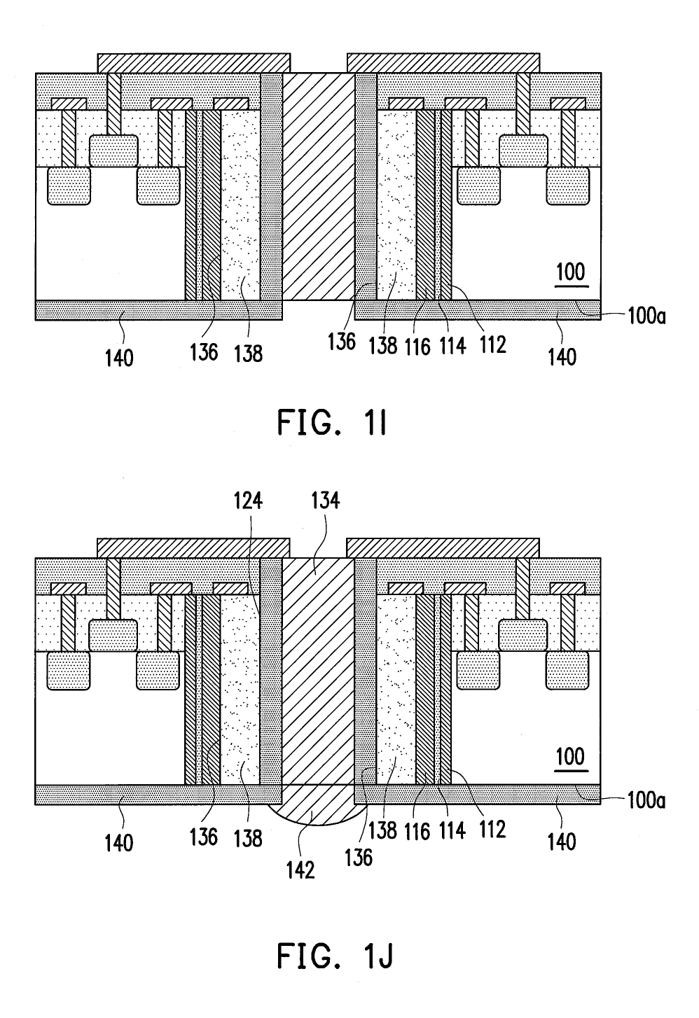

FIGS. 1A-1J are schematic cross-sectional views illustrating a process flow for manufacturing a through-silicon-via according to one embodiment of the present invention.

Referring to FIG. 1A, a fabricating method described in this embodiment may be integrated with the current IC fabricating process. Hence, a front-end transistor fabricating process may be carried out before manufacturing the through-silicon-via. The said front-end transistor fabricating process is, for example, to form a transistor 106 each constituted of a gate 102 and two source/drain 104 on a silicon substrate 100 and then cover the silicon substrate 100 with an inner dielectric (ILD) layer 108. The position and number of the transistor 106 in FIG. 1A may be varied to meet the actual requirements, and the present invention is not limited to the above.

Then, referring to FIG. 1B, a dry etching process is adopted to form a first annular trench 110 in the silicon substrate 100, wherein a dry etching gas used in this process is Cl₂, CF₄, or HBr, for example. Because a capacitor would be disposed at a position of the first annular trench 110 later, the first annular trench 110 may be formed adjacent to the transistor 106. It is noted that FIG. 1B merely illustrates the cross-sectional view of the structure, and thus the first annular trenches 110 shown in FIG. 1B is single trench.

Thereafter, referring to FIG. 1C, a first conductive layer 112, a capacitor dielectric layer 114, and a second conductive layer 116 are formed in the first annular trench 110 according to the following steps, for example. At first, the first conductive layer 112 is conformally deposited on a surface of the inner dielectric layer 108 of the silicon substrate 100 and an inner surface of the first annular trench 110, and the capacitor dielectric layer 114 is conformally deposited on the first conductive layer 112. Next, the second conductive layer 116 is filled into a space formed by the capacitor dielectric layer 114. Finally, a chemical mechanical polishing (CMP) process is performed to remove the first conductive layer 112, the capacitor dielectric layer 114, and the second conductive layer 116 outside the first annular trench 110. Moreover, a material of the first conductive layer 112 or the second conductive layer 116 is TiN, TaN, Ru, or Pt, for example. The capacitor dielectric layer 114 may be formed by a high-k material, such as Ta₂O₅, Al₂O₃, HfO₂, or TiO₂.

Then, referring to FIG. 1D, a process contact layer 118 is disposed in the inner dielectric layer 108 to be in contact with the source/drain 104, and M1 (Metal 1) 120a-c are formed on the inner dielectric layer 108, wherein M1 120a is connected with the process contact layer 118 only, M1 120b is connected with the first conductive layer 112 and the process contact layer 118, and M1 120c is connected with the first conductive layer 112 and the second conductive layer 116. It is noted that the positions of the process contact layer 118 and the M1 120a-c may be varied to meet the requirements of design. Following that, an inner metal dielectric (IMD) layer 122 is formed on the silicon substrate 100 to cover the M1 120a-c.

Next, referring to FIG. 1E, a dry etching process is carried out to form an opening 124 in the silicon substrate 100 surrounded by the first annular trench 110, the inner dielectric layer 108, and the inner metal dielectric layer 122, wherein a dry etching gas used in this process is Cl₂, CF₄, or HBr, for example. The opening 124 may be separated from the first annular trench 110 for a distance, as shown in FIG. 1E, or be positioned adjacent to the first annular trench 110 to reduce an area of the structure.

Thereafter, referring to FIG. 1F, an insulating layer 126 is formed on an inner surface of the opening 124, and a material of the insulating layer 126 is, for example, an oxide, such as SiO₂, or a nitride, such as SiN. Then, a conductive material 128 is filled into the opening 124. The conductive material 128 is Cu, W, an alloy of Cu or W, or Poly-Si, for instance. Further, a contact 130 may be formed in the inner dielectric layer 108 and the inner metal dielectric layer 122 to be in contact with the gate 102, and M2 (Metal 2) 132 is then disposed on the inner metal dielectric layer 122 to connect the contact 130, wherein the M2 132 may also be connected with the conductive material 128 to meet the requirements of design.

Next, with reference to FIG. 1G, a planarization process is performed on a back 100a of the silicon substrate 100 for removing a portion of the silicon substrate 100, which simultaneously removes the insulating layer 126 from the bottom of the opening 124 to form a conductive through-via 134 and removes the first conductive layer 112 and the capacitor dielectric layer 114 from a bottom of the first annular trench 110. To be more specific, the planarization process is, for example, a chemical mechanical polishing process.

Following that, referring to FIG. 1H, the silicon substrate 100, the first conductive layer 112, and the capacitor dielectric layer 114 located between the insulating layer 126 and the second conductive layer 116 are removed to form a second annular trench 136. The remaining first conductive layer 112, capacitor dielectric layer 114, and second conductive layer 116 together serve as a metal-insulator-metal (MIM) capacitor.

Next, referring to FIG. 1I, a low-k material 138 is filled into the second annular trench 136. The low-k material 138 is FSQ, hydrogen silsesquioxane (HSQ), or methyl silsesquioxane (MSQ), for instance. Thereafter, an insulating thin film 140 is formed on the back 100a of the silicon substrate 100 to cover the low-k material 138, the first conductive layer 112, the capacitor dielectric layer 114, and the second conductive layer 116. To be more specific, the aforesaid insulating thin film 140 may be an oxide such as SiO₂ or a nitride such as SiN.

Finally, referring to FIG. 1J, a bump 142 contacting the conductive through-via 134 on the bottom of the opening 124 is formed for bonding other chips. The bump 142 is, for example, a gold bump, a PbSn bump, a CuSn bump, or a CoSn bump.

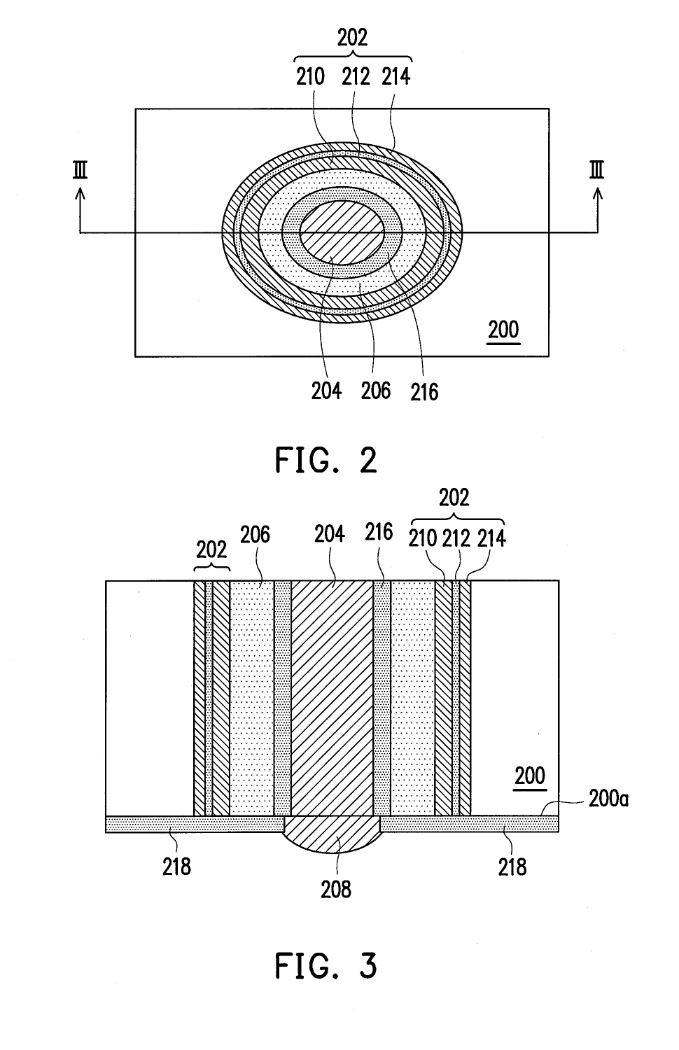

FIG. 2 illustrates a schematic top view of a through-silicon-via structure having a capacitance function according to another embodiment of the present invention; and FIG. 3 is a schematic cross-sectional view along Line III-III in FIG. 2.

With reference to FIGS. 2 and 3, the through-silicon-via structure with capacitance function described in this embodiment includes a silicon substrate 200, an annular capacitor 202, a conductive through-via 204, a layer of low-k material 206, and a bump 208. The annular capacitor 202 is disposed inside the silicon substrate 200 and has an outer diameter above 1 μm and below 100 μm, for example. Moreover, the annular capacitor 202 is constituted of a first conductive layer 210, a capacitor dielectric layer 212, and a second conductive layer 214 from the inside to the outside. A material of the first conductive layer 210 or the second conductive layer 214 is TiN, TaN, Ru, or Pt, for example. The capacitor dielectric layer 212 may be formed by a high-k material, such as Ta₂O₅, Al₂O₃, HfO₂, or TiO₂. The aforesaid conductive through-via 204 is disposed in the silicon substrate 200 surrounded by the annular capacitor 202, and a material of the conductive through-via 204 is Cu, W, an alloy of Cu or W, or Poly-Si, for instance. The layer of low-k material 206 is positioned between the annular capacitor 202 and the conductive through-via 204, wherein the layer of low-k material 206 is, for example, formed by FSQ, HSQ, or MSQ. The bump 208 is arranged to be in contact with the conductive through-via 204, so as to bond other chips, wherein the bump 208 may be a gold bump, a PbSn bump, a CuSn bump, or a CoSn bump. In this embodiment, an insulating layer 216 may be further disposed between the layer of low-k material 206 and the conductive through-via 204, and a material thereof is an oxide such as SiO₂ or a nitride such as SiN. Furthermore, in this embodiment, an insulating thin film 218 may be added onto a back 200a of the silicon substrate 200 to cover a bottom of the annular capacitor 202 and further extend between the bump 208 and the layer of low-k material 206. Specifically, the aforesaid insulating thin film 218 may be an oxide such as SiO₂ or a nitride such as SiN.

In conclusion of the above, the present invention uses semiconductor fabricating processes to manufacture the through-silicon-via structure combined with the annular capacitor, so as to accomplish the through-silicon-via (TSV) structure with capacitance function. Through the fabricating technology, the TSV can not only be used for transmitting signals but also be integrated with the functions of other passive devices. Accordingly, the TSV of the present invention has more functionality and value in 3D IC fabricating integration.

Although the present invention has been disclosed by the above embodiments, they are not intended to limit the present invention. Any person having ordinary knowledge in the art may make modifications and variations without departing from the spirit and scope of the present invention. Therefore, the protection scope sought by the present invention falls in the appended claim.

What is claimed is:

1. A method for fabricating a through-silicon-via, at least comprising:
forming a first annular trench in a silicon substrate;
forming a first conductive layer, a capacitor dielectric layer, and a second conductive layer in the first annular trench;
forming an opening in the silicon substrate surrounded by the first annular trench;
disposing an insulating layer on an inner surface of the opening;
filling a conductive material into the opening;
performing a planarization process on a back of the silicon substrate for removing a portion of the silicon substrate, which simultaneously removes the insulating layer from a bottom of the opening to form a conductive through-via and removes the first conductive layer and the capacitor dielectric layer from a bottom of the first annular trench;
removing the silicon substrate, the first conductive layer, and the capacitor dielectric layer between the insulating layer and the second conductive layer to form a second annular trench;
filling a low-k material into the second annular trench; and
forming a bump to be in contact with the conductive through-via on the bottom of the opening.

2. The fabricating method as claimed in claim 1, wherein a method for forming the first annular trench comprises dry etching.

3. The fabricating method as claimed in claim 2, wherein a dry etching gas for forming the first annular trench comprises Cl₂, CF₄, or HBr.

4. The fabricating method as claimed in claim 1, wherein a step of forming the first conductive layer, the capacitor dielectric layer, and the second conductive layer in the first annular trench comprises:
conformally depositing the first conductive layer on the silicon substrate and the inner surface of the first annular trench;
conformally depositing the capacitor dielectric layer on a surface of the first conductive layer;
filling the second conductive layer into a space formed by the capacitor dielectric layer; and
using a chemical mechanical polishing (CMP) process to remove the first conductive layer, the capacitor dielectric layer, and the second conductive layer outside the first annular trench.

5. The fabricating method as claimed in claim 1, wherein a material of the first conductive layer or the second conductive layer comprises TiN, TaN, Ru, or Pt.

6. The fabricating method as claimed in claim 1, wherein the capacitor dielectric layer is formed by a high-k material.

7. The fabricating method as claimed in claim 6, wherein a material of the capacitor dielectric layer comprises Ta₂O₅, Al₂O₃, HfO₂, or TiO₂.

8. The fabricating method as claimed in claim 1, wherein a method for forming the opening comprises dry etching.

9. The fabricating method as claimed in claim 8, wherein a dry etching gas for forming the opening comprises Cl₂, CF₄, or HBr.

10. The fabricating method as claimed in claim 1, wherein a material of the insulating layer comprises an oxide or a nitride.

11. The fabricating method as claimed in claim 1, wherein the conductive material comprises Cu, W, an alloy of Cu or W, or Poly-Si.

12. The fabricating method as claimed in claim 1, wherein the planarization process comprises a chemical mechanical polishing process.

13. The fabricating method as claimed in claim 1, wherein the low-k material comprises FSQ, hydrogen silsesquioxane (HSQ), or methyl silsesquioxane (MS Q).

14. The fabricating method as claimed in claim 1, wherein after filling the low-k material into the second annular trench and before forming the bump, the method further comprises: disposing an insulating thin film on the back of the silicon substrate to cover the low-k material, the first conductive layer, the capacitor dielectric layer, and the second conductive layer.

15. The fabricating method as claimed in claim 14, wherein the insulating thin film comprises an oxide or a nitride.

16. The fabricating method as claimed in claim 1, wherein the bump comprises a gold bump, a PbSn bump, a CuSn bump, or a CoSn bump.

17. A through-silicon-via structure, at least comprising:
a silicon substrate;
an annular capacitor disposed in the silicon substrate and constituted of a first conductive layer, a capacitor dielectric layer, and a second conductive layer form the inside to the outside;
a conductive through-via disposed in the silicon substrate surrounded by the annular capacitor;
a layer of low-k material located between the annular capacitor and the conductive through-via; and
a bump contacting a bottom of the conductive through-via.

18. The through-silicon-via structure as claimed in claim 17, wherein an outer diameter of the annular capacitor is above 1 μm and below 100 μm.

19. The through-silicon-via structure as claimed in claim 17, wherein a material of the first conductive layer or the second conductive layer comprises TiN, TaN, Ru, or Pt.

20. The through-silicon-via structure as claimed in claim 17, wherein the capacitor dielectric layer is formed by a high-k material.

21. The through-silicon-via structure as claimed in claim 20, wherein a material of the capacitor dielectric layer comprises Ta₂O₅, Al₂O₃, HfO₂, or TiO₂.

22. The through-silicon-via structure as claimed in claim 17, further comprising an insulating layer disposed between the layer of low-k material and the conductive through-via.

23. The through-silicon-via structure as claimed in claim 22, wherein a material of the insulating layer comprises an oxide or a nitride.

24. The through-silicon-via structure as claimed in claim 17, wherein a material of the conductive through-via comprises Cu, W, an alloy of Cu or W, or Poly-Si.

25. The through-silicon-via structure as claimed in claim 17, wherein the layer of low-k material comprises FSQ, hydrogen silsesquioxane (HSQ), or methyl silsesquioxane (MSQ).

26. The through-silicon-via structure as claimed in claim 17, further comprising an insulating thin film disposed on the back of the silicon substrate to cover a bottom of the annular capacitor.

27. The through-silicon-via structure as claimed in claim 26, wherein the insulating thin film comprises an oxide or a nitride.

28. The through-silicon-via structure as claimed in claim 17, wherein the bump comprises a gold bump, a PbSn bump, a CuSn bump, or a CoSn bump.
